(19) United States
(12) Patent Application Publication
(10) Pub. No.: US 2026/0244800 A1
(43) Pub. Date: Aug. 20, 2026

(54) SYSTEM AND METHOD FOR GENERATING DIGITAL SHINGLE LAYOUT

(71) Applicant: 3M INNOVATIVE PROPERTIES COMPANY, St. Paul, MN (US)

(72) Inventors: Hale R. Thomas, Winnetka, IL (US); Lisa V. Brown, Woodbury, MN (US); Lara K.N. Ughetta, Woodbury, MN (US)

(21) Appl. No.: 19/054,629

(22) Filed: Feb. 14, 2025

(51) Int. Cl. G06F 30/13

(52) U.S. Cl. CPC G06F 30/13

(57) ABSTRACT

The present disclosure provides a system for generating a digital shingle layout. The system includes a creator processing module configured to receive and process creator input parameters to generate a digital shingle layout and create a first matrix of digital color values (e.g., RGB) for the digital shingle layout. The creator input parameters include a geometry of a shingle outline and a digital shingle layout height which specifies the number of shingle outlines to be stacked in the digital shingle layout. The creator input parameters further include a shingle outline offset and a drop cycle. The system further includes a generator processing module configured to receive and process generator input parameters to generate the digital shingle layout and create a second matrix of digital color values for the digital shingle layout. The generator input parameters include the digital shingle layout and granule colors which specify colors for the granule blends having different identification numbers. The generator input parameters further include blend ratios.

### TECHNICAL FIELD

The present disclosure relates to a system and a method for generating a digital shingle layout.

### BACKGROUND

Asphalt-based roofing materials, such as roofing shingles, are widely used to protect buildings from rain, wind and sun, while providing an aesthetically pleasing appearance. Typically, roofing shingles are constructed using a substrate, such as a glass fiber mat coated with asphalt. A layer of granules is then embedded in the asphalt to enhance durability, weather resistance, and visual appeal. Conventionally, roofing shingles are produced by creating a continuous asphalt sheet, which is later cut into individual shingles. In this process, the substrate is passed through a hot liquid asphalt to form an asphalted coated sheet. Subsequently, the hot asphalt coated sheet is passed beneath one or more granule applicators, which deposit protective and decorative granules onto specific portions of the asphalt sheet according to a previously developed shingle design. For a given shingle design, this process requires extensive manual configuration, which can be time-consuming and resource-intensive, especially when developing new shingle designs, where several iterations may be required. Additionally, the conventional method introduces significant challenges in the visual evaluation of different shingle designs as every time a physical sample of the roofing shingle layout must be constructed, which increases wastage of material.

Therefore, there is a need for a method and/or a system which can reduce the number of physical sample iterations required in the development of new shingle designs, therefore reducing production costs and time, minimizing waste, and enabling exploration of more complex or customized configurations.

### SUMMARY

In some embodiments, the present disclosure provides a system for generating a digital shingle layout. The system can include a creator processing module configured to receive and process creator input parameters to generate a digital shingle layout and create a first matrix of digital color values for the digital shingle layout. The creator input parameters may include a geometry of a shingle outline, where the shingle outline corresponds to an exposed portion of a shingle in end-use application. The creator input parameters can further include a digital shingle layout height, which specifies the number of shingle outlines to be stacked in the digital shingle layout, and a shingle outline offset, which specifies a lateral offset between every two adjacent shingle outlines for offsetting alignment of the shingle outlines in the digital shingle layout. Additionally, the creator input parameters may include a drop cycle parameter selected from a group: identification numbers for specific granule blends to be dropped in different drop regions in the digital shingle layout, the width of each drop region, an order of dropping the granule blends in different drop regions, and the location of drop regions relative to one another.

The system may further include a generator processing module configured to receive and process generator input parameters to generate the digital shingle layout and create a second matrix of digital color values for the digital shingle layout. The generator input parameters can include the digital shingle layout, granule colors which specify colors for the granule blends having different identification numbers, and blend ratios which specify corresponding volume or mass percentage of granules in each granule blend.

In some embodiments, the geometry of the shingle outline can include a height of teeth, a shape of teeth, and a lateral spacing between sequential edges of teeth. The geometry of the shingle outline may be a default geometry or a customized geometry. Upon receiving the creator input parameter corresponding to the geometry of the shingle outline, the creator processing module can generate a shingle outline matrix comprising digital color values defining edges of the shingle outline. Upon generating the shingle outline matrix and upon receiving the creator input parameters corresponding to the digital shingle layout height and the shingle outline offset, the creator processing module can generate a blank digital shingle layout and create a matrix of digital color values for the blank digital shingle layout.

The creator input parameters may further include a shadow band height, which specifies a height of a shadow band in each shingle outline in the digital shingle layout. Upon generating the blank digital shingle layout and upon receiving the creator input parameters corresponding to the shadow band height and the drop cycle, the creator processing module can generate the digital shingle layout and create the first matrix of digital color values for the digital shingle layout. The creator processing module may further generate the digital shingle layout by replacing the digital color values in the matrix of the blank digital shingle layout with digital color values representing granule blends at corresponding locations for drop regions and shadow bands. The creator processing module can also convert the first matrix of digital color values for the digital shingle layout to an image file format, making the image file format of the digital shingle layout exportable.

Upon receiving the generator input parameters corresponding to the digital shingle layout, the generator processing module can evaluate each given digital color value in the first matrix of digital color values for the digital shingle layout and verify if each given digital color value corresponds to a granule blend. Upon verifying that a given digital color value does not correspond to the granule blend, the generator processing module can determine that the given digital color value corresponds to the shingle outline edge and retain that digital color value in the first matrix of digital color values for the digital shingle layout. Upon verifying that a given digital color value corresponds to the granule blend and upon receiving the generator input parameters corresponding to the granule colors and blend ratios, the generator processing module can randomly select a preliminary granule digital color value based on corresponding granule colors and blend ratios.

Upon selecting the preliminary granule RGB value, the generator processing module can verify if the given digital color value corresponds to a drop region. Upon verifying that the given digital color value does not correspond to the drop region, the generator processing module can determine that the given digital color value corresponds to a shadow band and replace the given digital color value with the preliminary granule digital color value. The generator processing module can further adjust the preliminary granule digital color value to imitate realistic granule color variation to generate a new digital color value and replace the preliminary granule digital color value with the new digital color value.

The generator input parameters may further include a gradient width at boundaries between different drop regions in the digital shingle layout. Upon verifying that the given digital color value corresponds to the drop region and upon receiving the generator input parameter corresponding to the gradient width, the generator processing module can verify if the given digital color value is within a gradient region defined by the gradient width. Upon verifying that the given digital color value is outside the gradient region, the generator processing module can replace the given digital color value with the preliminary granule digital color value. The generator processing module can further adjust the preliminary granule digital color value to imitate realistic granule color variation to generate a new digital color value and replace the preliminary granule digital color value with the new digital color value.

Upon verifying that the given digital color value is within the gradient region and upon receiving the generator input parameters corresponding to the granule colors and blend ratios, the generator processing module can check whether to change the preliminary granule digital color value to a gradient modified granule digital color value corresponding to a neighboring drop region. Upon checking that the preliminary granule digital color value is not to be changed to the gradient modified granule RGB value, the generator processing module can replace the given digital color value with the preliminary granule digital color value. The generator processing module can further adjust the preliminary granule digital color value to imitate realistic granule color variation to generate a new digital color value and replace the preliminary granule digital color value with the new digital color value.

Upon checking that the preliminary granule digital color value is to be changed to the gradient modified granule RGB value, the generator processing module can replace the given digital color value with the gradient modified granule digital color value. The generator processing module can further adjust the gradient modified granule digital color value to imitate realistic granule color variation to generate a new digital color value and replace the gradient modified granule digital color value with the new digital color value.

Upon evaluating each given digital color value in the first matrix of digital color values for the digital shingle layout, the generator processing module can generate the digital shingle layout and create the second matrix of digital color values for the digital shingle layout by replacing each given digital color value in the digital shingle layout with a corresponding evaluated digital color value. The generator processing module can further convert the second matrix of digital color values for the digital shingle layout to an image file format, making the image file format of the digital shingle layout exportable.

In some embodiments, the system and method described herein provide a flexible and efficient way to generate digital shingle layouts, allowing for precise control over the appearance and design of shingles. By enabling the use of various color spaces and providing tools for dynamic color conversion and customization, the system can enhance the ability to create detailed and visually appealing shingle designs.

In some embodiments, the geometry of the shingle outline can include a height of teeth, a shape of teeth, and a lateral spacing between sequential edges of teeth. The geometry of the shingle outline may be a default geometry or a customized geometry. Upon receiving the creator input parameter corresponding to the geometry of the shingle outline, the creator processing module can generate a shingle outline matrix comprising digital color values defining edges of the shingle outline. Upon generating the shingle outline matrix and upon receiving the creator input parameters corresponding to the digital shingle layout height and the shingle outline offset, the creator processing module can generate a blank digital shingle layout and create a matrix of digital color values for the blank digital shingle layout.

In some embodiments, the creator input parameters may further include a shadow band height, which specifies a height of a shadow band in each shingle outline in the digital shingle layout. Upon generating the blank digital shingle layout and upon receiving the creator input parameters corresponding to the shadow band height and the drop cycle, the creator processing module can generate the digital shingle layout and create the first matrix of digital color values for the digital shingle layout. The creator processing module may further generate the digital shingle layout by replacing the digital color values in the matrix of the blank digital shingle layout with digital color values representing granule blends at corresponding locations for drop regions and shadow bands. The creator processing module can also convert the first matrix of digital color values for the digital shingle layout to an image file format, making the image file format of the digital shingle layout exportable.

In some embodiments, upon receiving the generator input parameters corresponding to the digital shingle layout, the generator processing module can evaluate each given digital color value in the first matrix of digital color values for the digital shingle layout and verify if each given digital color value corresponds to a granule blend. Upon verifying that a given digital color value does not correspond to the granule blend, the generator processing module can determine that the given digital color value corresponds to the shingle outline edge and retain that digital color value in the first matrix of digital color values for the digital shingle layout. Upon verifying that a given digital color value corresponds to the granule blend and upon receiving the generator input parameters corresponding to the granule colors and blend ratios, the generator processing module can randomly select a preliminary granule digital color value based on corresponding granule colors and blend ratios.

In some embodiments, upon selecting the preliminary granule RGB value, the generator processing module can verify if the given digital color value corresponds to a drop region. Upon verifying that the given digital color value does not correspond to the drop region, the generator processing module can determine that the given digital color value corresponds to a shadow band and replace the given digital color value with the preliminary granule digital color value. The generator processing module can further adjust the preliminary granule digital color value to imitate realistic granule color variation to generate a new digital color value and replace the preliminary granule digital color value with the new digital color value.

In some embodiments, the generator input parameters may further include a gradient width at boundaries between different drop regions in the digital shingle layout. Upon verifying that the given digital color value corresponds to the drop region and upon receiving the generator input parameter corresponding to the gradient width, the generator processing module can verify if the given digital color value is within a gradient region defined by the gradient width. Upon verifying that the given digital color value is outside the gradient region, the generator processing module can replace the given digital color value with the preliminary granule digital color value. The generator processing module can further adjust the preliminary granule digital color value to imitate realistic granule color variation to generate a new digital color value and replace the preliminary granule digital color value with the new digital color value.

In some embodiments, upon verifying that the given digital color value is within the gradient region and upon receiving the generator input parameters corresponding to the granule colors and blend ratios, the generator processing module can check whether to change the preliminary granule digital color value to a gradient modified granule digital color value corresponding to a neighboring drop region. Upon checking that the preliminary granule digital color value is not to be changed to the gradient modified granule RGB value, the generator processing module can replace the given digital color value with the preliminary granule digital color value. The generator processing module can further adjust the preliminary granule digital color value to imitate realistic granule color variation to generate a new digital color value and replace the preliminary granule digital color value with the new digital color value.

In some embodiments, upon checking that the preliminary granule digital color value is to be changed to the gradient modified granule RGB value, the generator processing module can replace the given digital color value with the gradient modified granule digital color value. The generator processing module can further adjust the gradient modified granule digital color value to imitate realistic granule color variation to generate a new digital color value and replace the gradient modified granule digital color value with the new digital color value.

In some embodiments, upon evaluating each given digital color value in the first matrix of digital color values for the digital shingle layout, the generator processing module can generate the digital shingle layout and create the second matrix of digital color values for the digital shingle layout by replacing each given digital color value in the digital shingle layout with a corresponding evaluated digital color value. The generator processing module can further convert the second matrix of digital color values for the digital shingle layout to an image file format, making the image file format of the digital shingle layout exportable.

In some embodiments, the system and method described herein provide a flexible and efficient way to generate digital shingle layouts, allowing for precise control over the appearance and design of shingles. By enabling the use of various color spaces and providing tools for dynamic color conversion and customization, the system can enhance the ability to create detailed and visually appealing shingle designs.

The details of one or more examples of the disclosure are set forth in the accompanying drawings and the description below. Other features, objects, and advantages of the disclosure will be apparent from the description and drawings, and from the claims.

### BRIEF DESCRIPTION OF THE DRAWINGS

Exemplary embodiments disclosed herein may be more completely understood in consideration of the following detailed description in connection with the following figures. The figures are not necessarily drawn to scale. Like numbers used in the figures refer to like components. However, it will be understood that the use of a number to refer to a component in a given figure is not intended to limit the component in another figure labeled with the same number.

FIG. 1 is a schematic block diagram of a system for generating a digital shingle layout, in accordance with an embodiment of the present disclosure;

FIG. 2 is a detailed flowchart of a process, performed by a creator processing module, for generating a digital shingle layout that is further used for generating a digital shingle layout, in accordance with an embodiment of the present disclosure;

FIG. 3 is a schematic of an exemplary shingle outline shape;

FIG. 4 is a schematic of an exemplary shingle layout prior to overlapping and trimming of shingle strips performed in a conventional manufacturing method of generating a shingle;

FIG. 5 is a schematic of an exemplary blank digital shingle layout used for generating the digital shingle layout, in accordance with an embodiment of the present disclosure;

FIG. 6 is a schematic of an exemplary digital shingle layout used for generating the digital shingle layout, in accordance with an embodiment of the present disclosure;

FIG. 7 is a detailed flowchart of a process, performed by a generator processing module, for generating the digital shingle layout based on the digital shingle layout generated by the process of FIG. 2, in accordance with an embodiment of the present disclosure.

FIG. 8A is a schematic of an exemplary drop region of a shingle illustrating a gradient width;

FIG. 8B is a schematic of another exemplary drop region of a shingle illustrating a gradient width;

FIG. 9 is a flowchart of a method for generating a digital shingle layout, in accordance with an embodiment of the present disclosure; and

FIG. 10 is a schematic block diagram of a computer system for generating a digital shingle layout, in accordance with an embodiment of the present disclosure.

### DETAILED DESCRIPTION

In the following description, reference is made to the accompanying figures that form a part thereof and in which various embodiments are shown by way of illustration. It is to be understood that other embodiments are condigital shingle layout and may be made without departing from the scope or spirit of the present disclosure. The following detailed description, therefore, is not to be taken in a limiting sense.

In the following disclosure, the following definitions are adopted.

As used herein, all numbers should be considered modified by the term “about”. As used herein, “a,” “an,” “the,” “at least one,” and “one or more” are used interchangeably.

The term “about”, unless otherwise specifically defined, means to a high degree of approximation (e.g., within +/−5% for quantifiable properties) but again without requiring absolute precision or a perfect match.

As used herein as a modifier to a property or attribute, the term “generally”, unless otherwise specifically defined, means that the property or attribute would be readily recognizable by a person of ordinary skill but without requiring absolute precision or a perfect match (e.g., within +/−20 % for quantifiable properties).

As used herein, “corresponding” indicates that two structural components are sized and shaped similar to each other and can be coupled with a minimum amount of friction. Thus, an opening “corresponding” to a member is sized slightly larger than the member so that the member can pass through the opening with a minimum amount of friction. This definition is changed when the two components are said to “snugly” fit together or “just correspond”. In that situation, the difference between the sizes of those components is even smaller, thereby increasing the amount of friction.

The term “geometry” refers to the specific dimensions and shape characteristics of the shingle outline. This includes parameters such as the height and shape of the teeth, the lateral spacing between sequential edges of the teeth, and any other dimensional attributes that define the physical structure of the shingle outline. The geometry can be either a default geometry, which refers to predefined dimensions, or a customized geometry, which can be tailored according to user and application requirements.

The term “digital shingle layout” refers to a virtual representation of a shingle arrangement created using digital color values and geometric parameters. This layout includes multiple shingle outlines stacked in a specified order, with each outline potentially having different lateral offsets and granule blends. The digital shingle layout is generated by the creator processing module and further refined by the generator processing module to create a detailed and visually accurate representation of the final shingle design.

The term “shingle outline offset” refers to the lateral displacement between adjacent shingle outlines in the digital shingle layout. This offset specifies how much each shingle outline is shifted horizontally relative to the one below it. The shingle outline offset can be defined as a set, list, or array of values, where each value corresponds to the offset for a specific shingle outline. The number of values in the set, list, or array is equal to the digital shingle layout height, and the order of values corresponds to the order of shingle outlines that are stacked in the digital shingle layout.

The term “edges” refers to the boundary lines that define the shape of the shingle outline. These edges include the sequential edges of the teeth and any other boundary lines that delineate the perimeter of the shingle outline. The edges are represented by digital color values in the shingle outline matrix, which is used to generate the blank digital shingle layout and the final digital shingle layout.

The term “blank digital shingle layout” refers to an initial, uncolored version of the digital shingle layout. This layout includes the geometric arrangement of shingle outlines, including their heights and lateral offsets, but does not yet incorporate the granule blends or shadow bands. The blank digital shingle layout serves as a template that is later populated with digital color values representing the granule blends and other design elements to create the final digital shingle layout.

The present disclosure provides a system for generating a digital shingle layout. The system includes a creator processing module configured to receive and process creator input parameters to generate a digital shingle layout and create a first matrix of digital color values for the digital shingle layout. The creator input parameters include a geometry of a shingle outline. The shingle outline corresponds to an exposed portion of a shingle in an end-use application. The creator input parameters further include a digital shingle layout height which specifies the number of shingle outlines to be stacked in the digital shingle layout. The creator input parameters further include a shingle outline offset which specifies a lateral offset between every two adjacent shingle outlines for offsetting alignment of the shingle outlines in the digital shingle layout. The creator input parameters further include a drop cycle which specifies identification numbers for granule blends to be dropped in different drop regions in the digital shingle layout, the width of each drop region, an order of dropping the granule blends in different drop regions, and the location of drop regions relative to one another. The system further includes a generator processing module configured to receive and process generator input parameters to generate the digital shingle layout and create a second matrix of digital color values for the digital shingle layout. The generator input parameters include the digital shingle layout. The generator input parameters further include granule colors to be used in the granule blends having different identification numbers. The generator input parameters further include blend ratios which specify the percentage of each granule blend to be comprised of each granule color.

The present disclosure further provides a method for generating a digital shingle layout. The method includes generating, by a creator processing module, a shingle outline matrix comprising digital color values defining edges of a shingle outline based on a creator input parameter corresponding to a geometry of the shingle outline. The method further includes creating, by the creator processing module, a blank digital shingle layout and a matrix of digital color values for the blank digital shingle layout using the shingle outline matrix and additional creator input parameters corresponding to a digital shingle layout height and a shingle outline offset. The method further includes generating, by the creator processing module, a digital shingle layout and a first matrix of digital color values for the digital shingle layout by incorporating the blank digital shingle layout and further creator input parameters corresponding to a shadow band height and a drop cycle. The method further includes evaluating, by a generator processing module, each digital color value in the first matrix of digital color values for the digital shingle layout based on generator input parameters corresponding to granule colors, blend ratios, and a gradient width. The method further includes generating, by the generator processing module, the digital shingle layout and a second matrix of digital color values for the digital shingle layout based on the evaluated digital color values.

The term “digital color values” refers to numerical representations of colors used in the digital shingle layout. These values are used to define the colors of various elements within the layout, such as the granule blends and shadow bands. Digital color values can be represented in different color spaces, with RGB (Red, Green, Blue) being one of the most commonly used formats. While RGB is a common format for digital color values, other color spaces can also be used. For example, LAB color space is another format that represents colors based on lightness (L) and color-opponent dimensions (A and B). LAB color space is often used in color correction and color matching applications because it is designed to be more perceptually uniform than RGB.

In some embodiments, the system may support multiple color spaces and allow the user to choose the preferred format for digital color values. The system can convert between different color spaces as needed to ensure accurate color representation and consistency across various applications.

By generating the digital shingle layout, the system and the method of the present disclosure may eliminate a need for physical samples of different designs of shingles, thereby significantly reducing time and resources required for generating various samples of shingles. Users may digitally explore and experiment with various shingle designs, enabling the system and the method of the present disclosure to meet individual preferences and requirements. Moreover, elimination of the physical shingle sample eliminates the use of material, labor, and machinery that is normally used in conventional shingle manufacturing processes. Further, the generation of the digital shingle layout may ensure accurate distribution of granules comparable to physical samples, thereby enabling the user to more efficiently choose desirable granule colors and blend ratios for improving the appearance of shingles.

Incorporation of the two separate modules, (i.e., the creator processing module and the generator processing module) in the system may reduce time required in generation of the shingle, thereby increasing efficiency of the overall process to develop new shingle designs. The creator processing module creates the digital shingle layout and the first matrix of digital color values for the digital shingle layout, and the generator processing module generates the digital shingle layout based on the digital shingle layout. Specifically, the creator processing module creates a digital shingle layout defining different regions in which different granule colors would be dropped by the generator processing module. Generally, the same digital shingle layout may be used multiple times by changing the blend ratios and digital color values of granules in order to have different shingle layout. Therefore, repeatedly running the creator processing module may be eliminated which may enhance efficiency, and potentially reduce processing load.

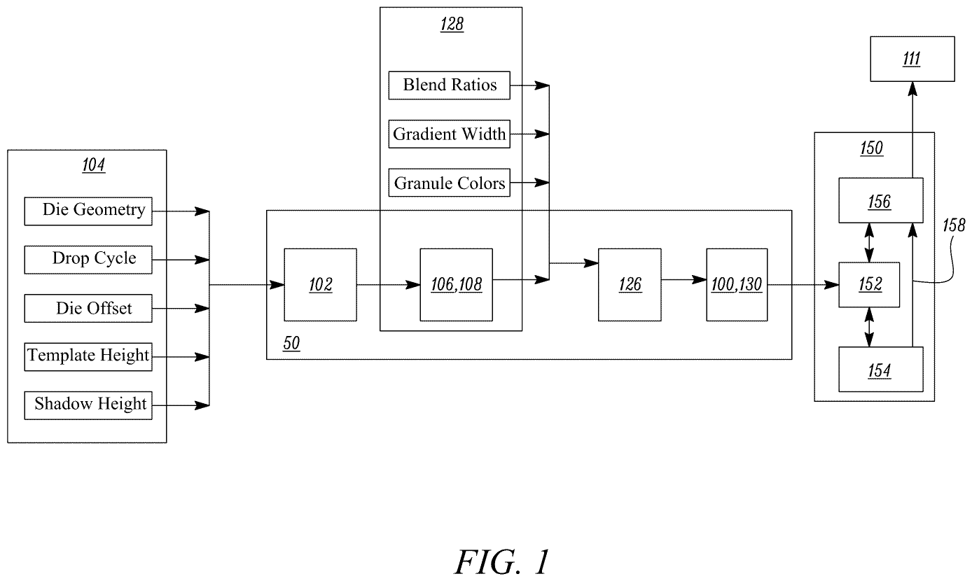

Referring now to Figures, FIG. 1 is a schematic block diagram of a system 50 for generating a digital shingle layout 100, according to an embodiment of the present disclosure. The system 50 includes a creator processing module 102 configured to receive and process creator input parameters 104 to generate a digital shingle layout 106 and create a first matrix 108 of digital color values for the digital shingle layout 106.

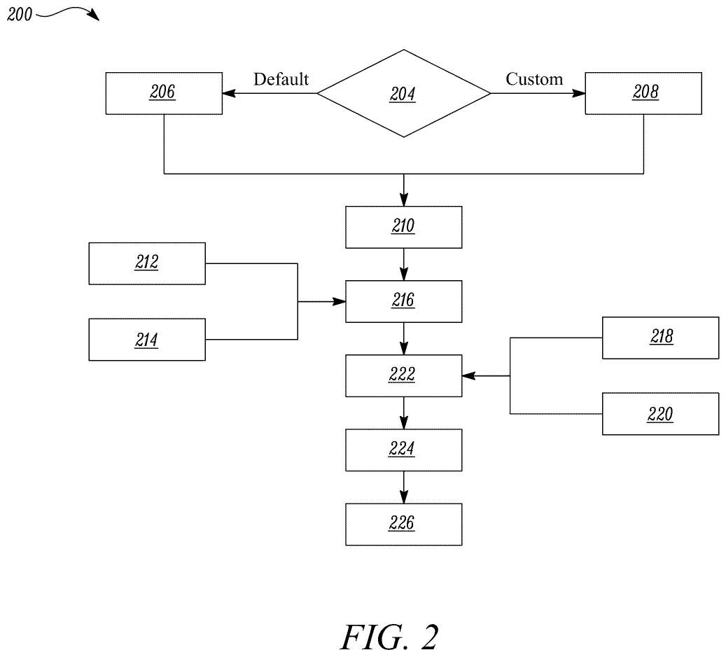

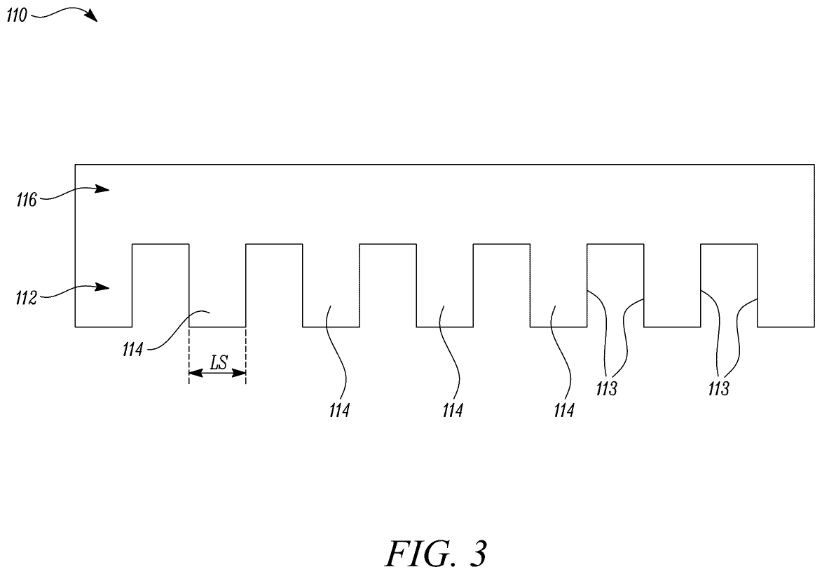

FIG. 2 is a detailed flowchart of a process 200, performed by the creator processing module 102, for generating the digital shingle layout 106 that is further used for generating the digital shingle layout 100, in accordance with an embodiment of the present disclosure. The creator input parameters 104 include a geometry of a shingle outline (e.g., a shingle outline 110 shown in FIG. 3). The shingle outline corresponds to an exposed portion of a shingle 111 in end-use application. At operation 204, a user provides the creator input parameter corresponding to the geometry of the shingle outline.

FIG. 3 is a schematic view of an exemplary shingle outline 110 used for generating the digital shingle layout 100. In some embodiments, the shingle outline 110 can refer to equipment that is used to cut shingle stock material into a shingle outline shape. Initially, the shingle stock material (i.e., the strip) may be in the form of a rectangular substrate, later the shingle stock material (i.e., the strip) is cut into the shape of the shingle outline 110 (as shown in FIG. 3). As shown in FIG. 3, the shingle outline 110 includes a first portion 112 defining a set of teeth 114 and a second portion 116 defined adjacent and above the first portion 112. Further, the teeth 114 define a lateral spacing LS between sequential edges 113 thereof. The geometry of the shingle outline 110 includes a height of teeth 114, a shape of teeth 114, and the lateral spacing LS between sequential edges 113 of teeth 114. In FIG. 3, the lateral spacing LS between sequential edges 113 of teeth 114 is the same. However, in some embodiments, the lateral spacing LS between sequential edges 113 of teeth 114 may vary based on application requirements. Further, the person skilled in the art may understand that only the first portion 112 of the shingle outline 110 would be exposed in the end-use application.

The geometry of the shingle outline 110 is a default geometry or a customized geometry. Default geometry refers to a predefined dimension of the shingle outline 110, for example, a predefined lateral spacing LS between each tooth 114 and a predefined height of the shingle outline 110. However, the geometry of the shingle outline 110 may be customized according to the user and application requirements. At operation 204, if the user chooses a default option for shingle outline geometry, the process 200 moves from operation 204 to operation 206, where the default shingle outline geometry is selected. At operation 204, if the user chooses a custom option for shingle outline geometry, the process 200 moves from operation 204 to operation 208, where the user provides customized shingle outline geometry.

The process 200 further moves to operation 210. Upon receiving the creator input parameters 104 corresponding to the geometry of the shingle outline 110 (at operation 204), the creator processing module 102 is configured to generate a shingle outline matrix including digital color values defining edges 113 of the shingle outline 110. At operation 210, the creator processing module 102 generates the shingle outline matrix. It should be noted that the sequential edges 113 of the teeth 114 would form shingle outline edges 113 of the shingle outline 110.

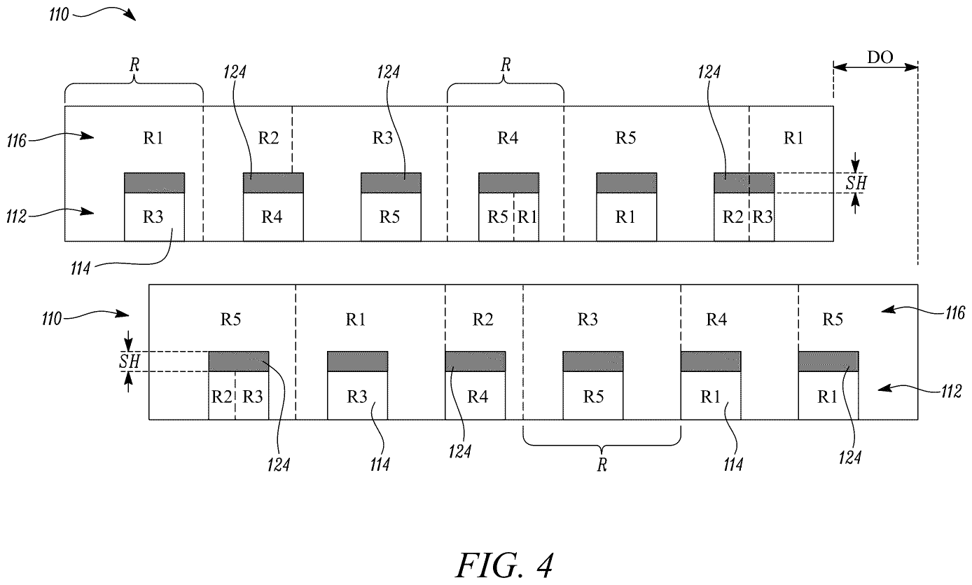

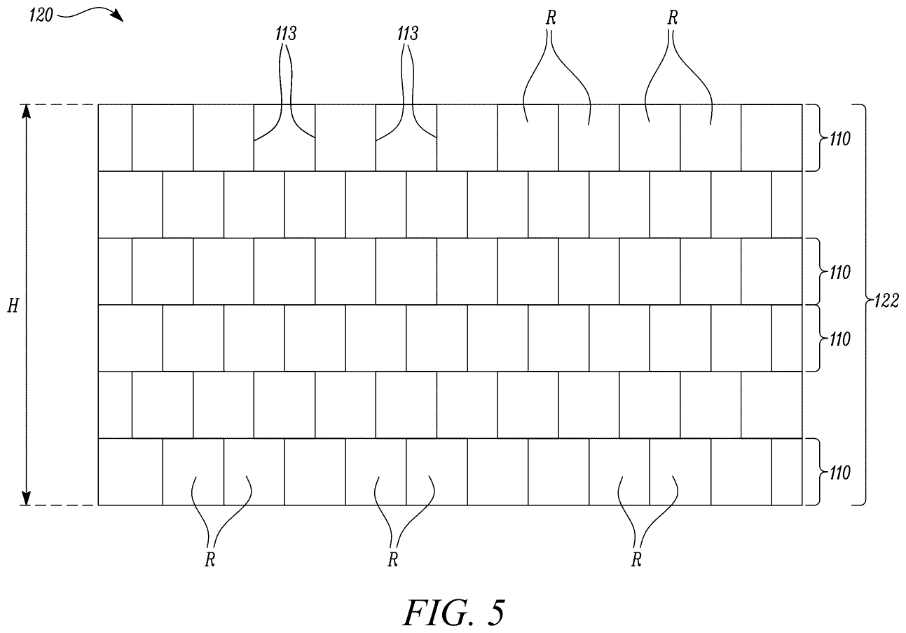

FIG. 4 is a schematic of an exemplary shingle layout prior to overlapping and trimming of shingle strips performed in a conventional manufacturing method of generating a shingle. FIG. 5 is a schematic of an exemplary blank digital shingle layout 120 used for generating the digital shingle layout 100, in accordance with an embodiment of the present disclosure.

Referring to FIGS. 1 to 5, the creator input parameters 104 further include a digital shingle layout height H (shown in FIG. 5) which specifies the number of shingle outlines 110 to be stacked in the digital shingle layout 106. At operation 212, the user provides the creator input parameter 104 corresponding to the digital shingle layout height H. The creator input parameters 104 further include a shingle outline offset DO (shown in FIG. 4) which specifies a lateral offset between every two adjacent shingle outlines 110 for offsetting alignment of the shingle outlines 110 in the digital shingle layout 106. At operation 214, the user provides the creator input parameter 104 corresponding to the shingle outline offset DO.

Upon generating the shingle outline matrix (at operation 210) and upon receiving the creator input parameters 104 corresponding to the digital shingle layout height H (at operation 212) and the shingle outline offset DO (at operation 216), the creator processing module 102 is configured to generate the blank digital shingle layout 120 and create a matrix 122 of digital color values for the blank digital shingle layout 120. At operation 216, the creator processing module 102 generates the shingle outline matrix.

As shown in FIG. 4, in the conventional manufacturing method of generating a shingle, the shingle outlines 110 are arranged on each other in a manner such that the first portion 112 of each shingle outline 110 is disposed on the second portion 116 of the adjacent shingle outline 110, thereby hiding the second portion 116 of each shingle outline 110 in the end-use application. In other words, the shingle outlines 110 are arranged such that the first portion 112 of each shingle outline 110 is arranged overlapping the second portion 116 of the adjacent shingle outline 110. Further, as shown in FIG. 4, adjacent shingle outlines 110 are stacked defining the lateral offset (i.e., shingle outline offset DO) between each other. Moreover, excess portions of each shingle outline 110 may be trimmed. In FIG. 4, only two shingle outlines 110 arranged on each other are shown. However, the number of shingle outlines 110 may vary based on the application requirements.

The creator input parameters 104 further include a drop cycle which specifies identification numbers for specific granule blends to be dropped in different drop regions R in the digital shingle layout 106, the width of each drop region, an order of dropping the granule blends in different drop regions R, and location of drop regions R relative to one another. At operation 218, the user provides the creator input parameter 104 corresponding to the drop cycle. In FIG. 4, six drop regions R labelled as R1, R2, R3, R4, R5, and R6 are shown but the number of drop regions may vary. Each of the drop regions R may have different widths, however, it may also be same based on application requirements. Each drop region R is configured to receive a predetermined granule blend in a predetermined order. In some embodiments, the granule blends can be defined to include various combinations of granule colors and blend ratios. Each granule blend is identified by a unique identification number, which specifies the specific combination of granule colors and their respective proportions. This identification number is used to determine which granule blend is to be applied in specific regions of the digital shingle layout.

In some embodiments, the system provides the capability to assign different granule blends to different drop regions within the digital shingle layout. For example, one drop region may receive a granule blend with a higher proportion of darker granules to create a shadow effect, while another drop region may receive a blend with lighter granules to enhance the visual appeal. The shadow band granule blend, which is used to create a shadow effect between the teeth of the shingle outline, can also be customized independently of the other granule blends.

This flexibility extends to the ability to place any granule blend in any location within the digital shingle layout. The user can define the drop cycle, which specifies the order and location of granule blends to be applied. This drop cycle can be adjusted to achieve the desired aesthetic effect, allowing for complex and intricate shingle designs. The system supports the use of both uniform and varied granule blends across different regions, enabling the creation of unique and visually appealing shingle layouts.

In some embodiments, the granule blends can be dynamically adjusted based on user input or predefined design rules. For instance, the user can specify a gradient effect, where the granule blend gradually changes from one region to another. This gradient effect can be achieved by defining a gradient width at the boundaries between different drop regions, allowing for a smooth transition of granule colors and blend ratios.

The creator input parameters 104 further include a shadow band height SH which specifies a height of a shadow band 124 in each shingle outline 110 in the digital shingle layout 106. At operation 220, the user provides the creator input parameter 104 corresponding to the shadow band height SH. The shadow band 124 is an optional feature located in the lateral spacing between the adjacent teeth 114, as shown in FIG. 4. The shadow band 124 may have a darker shade than the shingle outline 110. It should be noted that the shade of the shadow band 124 should be distinctly different to simulate bulk, highlight, shadow or any other aesthetic effect achievable by contrast with the exposed areas. If a shadow band is not desired, the user can set the shadow band height to 0 or null. This feature provides flexibility in the design of the digital shingle layout, allowing the user to customize the appearance of the shingles based on specific aesthetic preferences or functional requirements.

In some embodiments, the shadow band 124 is an optional feature that can be included or excluded from the digital shingle layout. The shadow band 124 typically refers to a darker region located between the teeth of the shingle outline, which creates a shadow effect that enhances the visual depth and texture of the shingles. However, there may be instances where the shadow band 124 is not required or desired, such as when a uniform appearance is preferred or when the design calls for a different visual effect.

To accommodate these variations, the system allows the user to set the shadow band height to 0 or null. When the shadow band height is set to 0 or null, the system may interpret this as an instruction to exclude the shadow band 124 from the digital shingle layout. As a result, the digital shingle layout may be generated without the shadow band 124, and the corresponding regions are filled with the granule blends specified for the adjacent drop regions.

In some embodiments, the system may provide a user interface that allows the user to specify the shadow band height through a graphical input or a text field. The user can enter the desired value for the shadow band height, and the system dynamically updates the digital shingle layout to reflect the specified value. If the user enters 0 or null, the system automatically excludes the shadow band 124 from the layout.

As shown in FIG. 5, the blank digital shingle layout 120 includes six shingle outlines 110 stacked on each other defining the digital shingle layout height H. However, the number of shingle outlines 110 in the blank digital shingle layout 120 may vary based on application requirements.

Upon generating the blank digital shingle layout 120 (at operation 216) and upon receiving the creator input parameters 104 corresponding to the shadow band height SH (at operation 220) and the drop cycle (at operation 218), the creator processing module 102 is configured to generate the digital shingle layout 106 and create the first matrix 108 of digital color values for the digital shingle layout 106. At operation 222, the creator processing module 102 generates the digital shingle layout 106.

The shingle outline offset can be redefined as a set, list, or array of values. This redefinition allows for a more flexible and precise specification of the lateral offset between adjacent shingle outlines in the digital shingle layout.

In at least one embodiment, the shingle outline offset can be represented as a set of values. Each value in the set corresponds to a specific lateral offset for a shingle outline in the digital shingle layout. The number of values in the set is equal to the digital shingle layout height, which specifies the number of shingle outlines to be stacked in the digital shingle layout. The order of values in the set corresponds to the order of shingle outlines that are stacked in the digital shingle layout. For example, if the digital shingle layout height is six, the set may include six values, each representing the lateral offset for one of the six shingle outlines.

In another embodiment, the shingle outline offset can be represented as a list of values. Similar to the set, each value in the list specifies the lateral offset for a corresponding shingle outline in the digital shingle layout. The list allows for an ordered collection of values, where the position of each value in the list corresponds to the position of the shingle outline in the digital shingle layout. This ordered structure ensures that the lateral offsets are applied sequentially as the shingle outlines are stacked.

In yet another embodiment, the shingle outline offset can be represented as an array of values. The array provides a structured format for storing the lateral offset values, with each element in the array representing the lateral offset for a specific shingle outline. The array's length is equal to the digital shingle layout height, ensuring that there is a one-to-one correspondence between the array elements and the shingle outlines. The order of values in the array corresponds to the stacking order of the shingle outlines in the digital shingle layout.

The redefinition of the shingle outline offset as a set, list, or array of values provides several advantages. It allows for precise control over the lateral offsets, enabling the creation of complex and customized shingle layouts. Additionally, it facilitates the digital representation and manipulation of the shingle layout, making it easier to generate and modify the digital shingle layout using computational methods.

In some embodiments, the values in the set, list, or array can be specified in units of measurement such as millimeters or inches. This allows for accurate and consistent application of the lateral offsets in the digital shingle layout. The values can also be specified as percentages of the shingle width, providing a relative measure of the lateral offset.

In other embodiments, the values in the set, list, or array can be dynamically generated based on user input or predefined rules. For example, the values can be calculated based on the desired visual effect or pattern in the shingle layout. This dynamic generation of values allows for greater flexibility and customization in the design of the digital shingle layout.

The redefinition of the shingle outline offset as a set, list, or array of values is an important aspect of the system and method for generating a digital shingle layout. It enhances the ability to create detailed and precise shingle layouts, reducing the need for physical samples and enabling efficient exploration of different shingle designs.

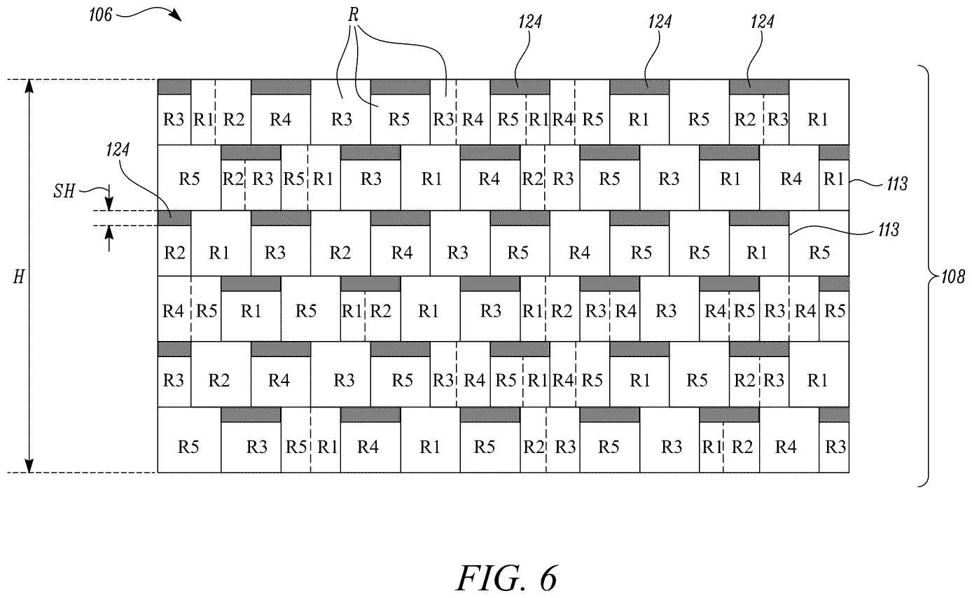

FIG. 6 is a schematic of an exemplary digital shingle layout 106 used for generating the digital shingle layout 100, in accordance with an embodiment of the present disclosure. The creator processing module 102 is further configured to generate the digital shingle layout 106 by replacing the digital color values in the matrix 122 of the blank digital shingle layout 120 with digital color values representing granule blends at corresponding locations for drop regions R and shadow bands 124.

The process 200 further moves to operation 224 where the creator processing module 102 is further configured to convert the first matrix 108 of digital color values for the digital shingle layout 106 to an image file format. The process 200 further moves to operation 226 where the image file format of the digital shingle layout 106 is exported. In other words, the image file format of the digital shingle layout 106 is exportable.

The term “exportable” refers to the capability of a digital shingle layout to be converted into a format that can be saved, shared, or transferred outside the digital shingle software. When a digital shingle layout is described as exportable, it means that the layout can be processed and formatted into a file type that is suitable for external use. This capability ensures that the digital shingle layout can be utilized in various applications, such as for review, modification, or integration with other systems.

In contrast, the term “exported” refers to the actual process of creating a file in the computer file system that contains the digital shingle layout. When a digital shingle layout is exported, it means that the layout has been converted into a specific file format and saved to the computer's file system. This exported file can be opened and viewed independently of the digital shingle software, using standard file viewers or editors that support the file format.

Referring back to FIG. 1, the system 50 further includes a generator processing module 126 configured to receive and process generator input parameters 128 to generate the digital shingle layout 100 and create a second matrix 130 of digital color values for the digital shingle layout 100. As shown in FIG. 1, the generator input parameters 128 include the digital shingle layout 106. The generator input parameters 128 further include granule colors which specify colors for the granule blends having different identification numbers. The generator input parameters 128 further include blend ratios which specify the percentage of each granule blend to be comprised of each granule color.

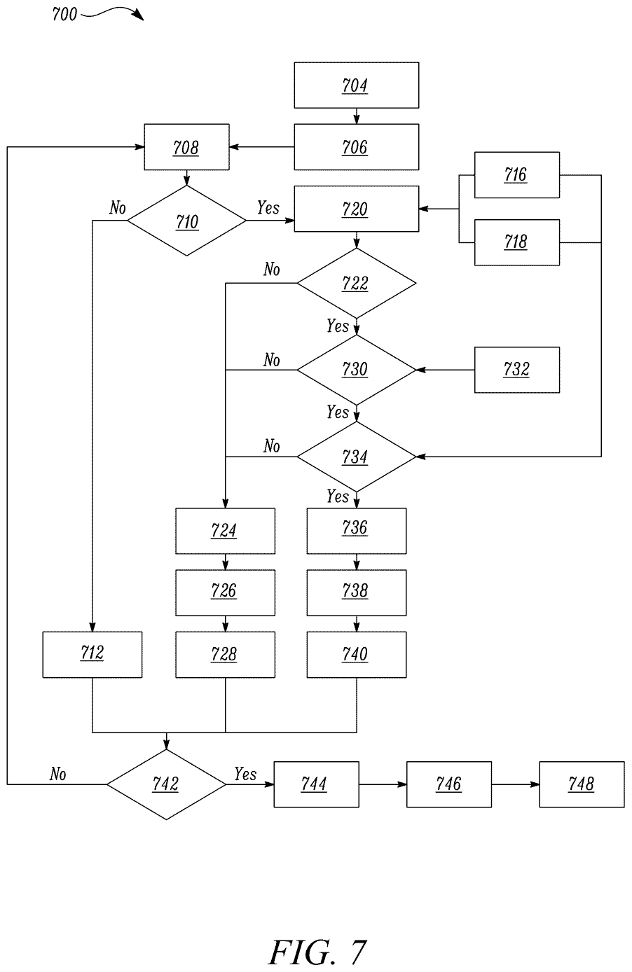

FIG. 7 is a detailed flowchart of a process 700, performed by the generator processing module 126, for generating the digital shingle layout 100 based on the digital shingle layout 106 generated by the process 200 of FIG. 2, in accordance with an embodiment of the present disclosure. Referring to FIGS. 1, 2 and 7, at operation 704, the user provides an image file of the digital shingle layout 106. The process 700 further moves to operation 706 where the generator processing module 126 is configured to convert the image file of the digital shingle layout 106 into the first matrix 108 of digital color values for the digital shingle layout 106.

The process 700 further moves to operation 708 where the generator processing module 126 is configured to evaluate each given digital color value in the first matrix 108 of digital color values for the digital shingle layout 106. The process 700 further moves to operation 710 where the generator processing module 126 is configured to verify if each given digital color value corresponds to a granule blend. In other words, upon receiving the generator input parameters 128 corresponding to the digital shingle layout 106, the generator processing module 126 is configured to evaluate each given digital color value in the first matrix 108 of digital color values for the digital shingle layout 106 and verify if each given digital color value corresponds to a granule blend.

Upon verifying that a given digital color value does not correspond to a granule blend, the process 700 moves to operation 712 where the generator processing module 126 is configured to determine that the given digital color value corresponds to the shingle outline edge 113 and retain that digital color value in the first matrix 108 of digital color values for the digital shingle layout 106. At operation 712, the generator processing module 126 determines that the given digital color value corresponds to the shingle outline edge 113 and retains that digital color value in the first matrix 108 of digital color values for the digital shingle layout 106.

At operation 716, the generator processing module 126 can intake the user-provided digital color values as input. These digital color values may be specified in various color spaces or formats, depending on the user's preference or the requirements of the design. The digital color values can be used to define the colors of granule blends and other elements within the digital shingle layout.

The system is designed to accept digital color values in multiple formats, such as RGB, LAB, CMYK, and others. This flexibility allows users to input color values in the format that is most convenient or familiar to them. For example, a user may choose to input colors in the RGB format, where each color is represented by three numerical values corresponding to the intensities of red, green, and blue components. Alternatively, a user may input colors in the LAB format, which represents colors based on lightness and color-opponent dimensions.

Upon receiving the digital color values, the generator processing module 126 may be responsible for converting these values to the appropriate format required for the matrix values used in the digital shingle layout. This conversion can ensure that the colors are accurately represented and consistent throughout the design process. The conversion process may involve translating the input color values from one color space to another, such as converting LAB values to RGB values, or adjusting the color values to match the specific requirements of the digital shingle layout.

The conversion process can involve several steps. First, the generator processing module 126 may identify the format of the user-provided digital color values. This could be specified by the user or automatically detected by the system based on the input data. Based on the identified input format and the required output format, the generator processing module 126 can select the appropriate color conversion algorithm. Standard color conversion algorithms may be used to ensure accurate and consistent color representation.

Next, the generator processing module 126 can perform the conversion by applying the selected algorithm to the input digital color values. For example, if the input values are in LAB format and the required format is RGB, the module may convert the LAB values to RGB values using the appropriate mathematical transformations. The generator processing module 126 can ensure that the converted color values maintain the desired level of precision and accuracy. This may involve rounding or scaling the values to fit the required format.

Finally, the converted digital color values can be stored in the appropriate data structures used by the system for generating the digital shingle layout. These values may be used to create the matrix of digital color values that define the colors of granule blends and other elements within the layout.

At operation 718, the user provides the generator input parameter 128 corresponding to the blend ratios.

Upon verifying that a given digital color value corresponds to a granule blend (at operation 710) and upon receiving the generator input parameters 128 corresponding to the granule colors and blend ratios (at operation 718), the generator processing module 126 is configured to randomly select a preliminary granule digital color value based on corresponding granule colors and blend ratios. At operation 720, the generator processing module 126 randomly selects the preliminary granule digital color value based on corresponding granule colors and blend ratios. In other words, upon verifying that a given digital color value corresponds to the granule blend, the process 700 moves to operation 720 where the generator processing module 126 selects the preliminary granule digital color value based on corresponding granule colors and blend ratios. The process 700 further moves to operation 722.

Upon selecting the preliminary granule digital color value, the generator processing module 126 is configured to verify if the given digital color value corresponds to a drop region R (shown in FIGS. 4 and 5). At operation 722, the generator processing module 126 verifies if the given digital color value corresponds to a drop region R.

Upon verifying that the given digital color value does not correspond to a drop region R, the generator processing module 126 is configured to determine that the given digital color value digital color value corresponds to the shadow band 124 and replace the given digital color value digital color value with the preliminary granule digital color value. At operation 722, if the generator processing module 126 determines that the given digital color value digital color value does not correspond to a drop region R, the process 700 moves to operation 724 where the generator processing module 126 replaces the given digital color value with the preliminary granule digital color value. The process 700 further moves to operation 726.

The generator processing module 126 is further configured to adjust the preliminary granule digital color value to imitate realistic granule color variation to generate a new digital color value and replace the preliminary granule digital color value with the new digital color value. At operation 726, the generator processing module 126 adjusts the preliminary granule digital color value to imitate realistic granule color variation to generate the new digital color value. The process 700 further moves to operation 728 where the generator processing module 126 replaces the preliminary granule digital color value with the new digital color value.

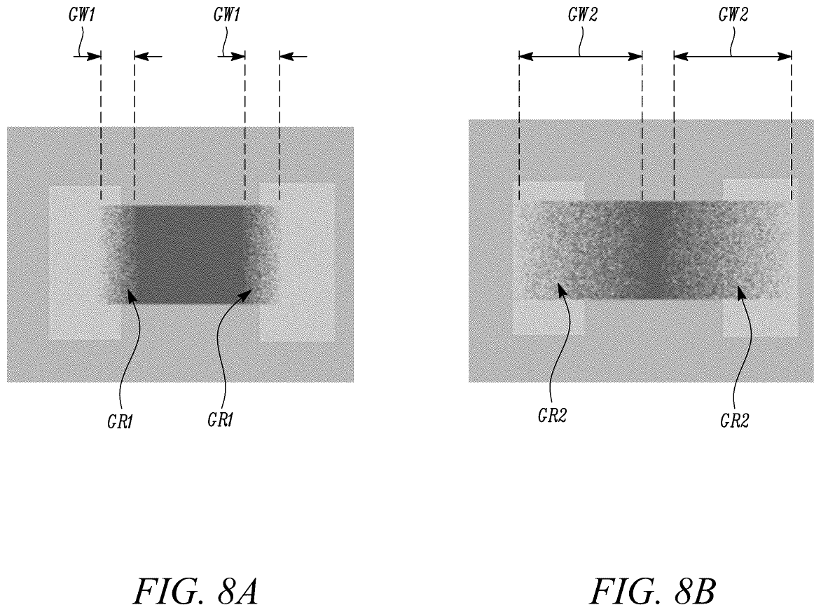

FIG. 8A is a schematic of an exemplary drop region of a shingle illustrating a gradient width GW1. FIG. 8A is a schematic of another exemplary drop region of a shingle illustrating a gradient width GW2. The generator input parameters 128 further include a gradient width (e.g., the gradient width GW1 as shown in FIG. 8A, or the gradient width GW2 as shown in FIG. 8B) at boundaries between different drop regions R in the digital shingle layout 106. The gradient width signifies distribution of the granules in the drop region. In FIG. 8A, the gradient width GW1 defines a gradient region GR1. In FIG. 8B, the gradient width GW2 defines a gradient region GR2. The gradient width GW2 is greater than the gradient width GW1. This means that the granules are relatively more widely distributed in the gradient region GR2.

Upon verifying that the given digital color value corresponds to the drop region R and upon receiving the generator input parameter 128 corresponding to the gradient width, the generator processing module 126 is configured to verify if the given digital color value is within the gradient region (e.g., the gradient region GR1 or the gradient region GR2) defined by the gradient width (e.g., the gradient width GW1 or the gradient width GW2).

At operation 722, if the generator processing module 126 determines that the given digital color value corresponds to the drop region R, the process 700 moves to operation 730 where the generator processing module 126 verifies if the given digital color value is within the gradient region. At operation 732, the user provides the generator input parameter corresponding to the gradient width.

Upon verifying that the given digital color value is outside the gradient region, the generator processing module 126 is configured to replace the given digital color value with the preliminary granule digital color value. At operation 730, if the generator processing module 126 verifies that the given digital color value is outside the gradient region, the process 700 moves to operation 724 where the generator processing module 126 replaces the given digital color value with the preliminary granule digital color value. The process 700 further moves to operation 726 where the generator processing module 126 adjusts the preliminary granule digital color value to imitate realistic granule color variation to generate the new digital color value. The process 700 further moves to operation 728 where the generator processing module 126 replaces the preliminary granule digital color value with the new digital color value.

Upon verifying that the given digital color value is within the gradient region and upon receiving the generator input parameters 128 corresponding to the granule colors and blend ratios, the generator processing module 126 is configured to check whether to change the preliminary granule digital color value to a gradient modified granule digital color value corresponding to a neighboring drop region R. At operation 730, if the generator processing module 126 verifies that the given digital color value is within the gradient region, the process 700 moves to operation 734 where the generator processing module 126 receives the generator input parameters 128 corresponding to the granule colors and blend ratios, and further checks whether to change the preliminary granule digital color value to the gradient modified granule digital color value corresponding to the neighboring drop region R.

Upon checking that the preliminary granule digital color value is not to be changed to the gradient modified granule digital color value, the generator processing module 126 is configured to replace the given digital color value with the preliminary granule digital color value. At operation 734, if the generator processing module 126 determines that the preliminary granule digital color value is not to be changed to the gradient modified granule digital color value, the process 700 moves to operation 724 where the generator processing module 126 replaces the given digital color value with the preliminary granule digital color value. The process 700 further moves to operation 726 where the generator processing module 126 adjusts the preliminary granule digital color value to imitate realistic granule color variation to generate the new digital color value. The process 700 further moves to operation 728 where the generator processing module 126 replaces the preliminary granule digital color value with the new digital color value.

Upon checking that the preliminary granule digital color value is to be changed to the gradient modified granule digital color value, the generator processing module 126 is configured to replace the given digital color value with the gradient modified granule digital color value. At operation 734, if the generator processing module 126 determines that the preliminary granule digital color value is to be changed to the gradient modified granule digital color value, the process 700 moves to operation 736 where the generator processing module 126 replaces the given digital color value with the gradient modified granule digital color value. The process 700 further moves to operation 738.

The generator processing module 126 is further configured to adjust the gradient modified granule digital color value to imitate realistic granule color variation to generate a new digital color value and replace the gradient modified granule digital color value with the new digital color value. At operation 738, the generator processing module 126 adjusts the gradient modified granule digital color value to imitate realistic granule color variation to generate the new digital color value. The process 700 further moves to operation 740 where the generator processing module 126 replaces the gradient modified granule digital color value with the new digital color value.

From each of the operations 712, 728, 740, the process 700 further moves to operation 742 where the generator processing module 126 verifies if all digital color values in the first matrix 108 associated with the digital shingle layout 106 have been evaluated. At operation 742, if the generator processing module 126 verifies that all digital color values in the first matrix 108 have not been evaluated, the process 700 moves back to operation 708 where the generator processing module 126 evaluates remaining given digital color values in the first matrix 108 of digital color values for the digital shingle layout 106.

At operation 742, if the generator processing module 126 verifies that all digital color values in the first matrix 108 have been evaluated, the process 700 moves to operation 744 where the generator processing module 126 generates the digital shingle layout 100. In other words, upon evaluating each given digital color value in the first matrix 108 of digital color values for the digital shingle layout 106, the generator processing module 126 is configured to generate the digital shingle layout 100. Moreover, the generator processing module 126 is further configured to create the second matrix 130 of digital color values for the digital shingle layout 100 by replacing each given digital color value in the digital shingle layout 106 with a corresponding evaluated digital color value. The process 700 further moves to operation 746.

The generator processing module 126 is further configured to convert the second matrix 130 of digital color values for the digital shingle layout 100 to an image file format. At operation 746, the generator processing module 126 converts the second matrix 130 of digital color values for the digital shingle layout 100 to the corresponding image file format. The process 700 further moves to operation 748 where the image file format of the digital shingle layout 100 is exported. In other words, the image file format of the digital shingle layout 100 is exportable.

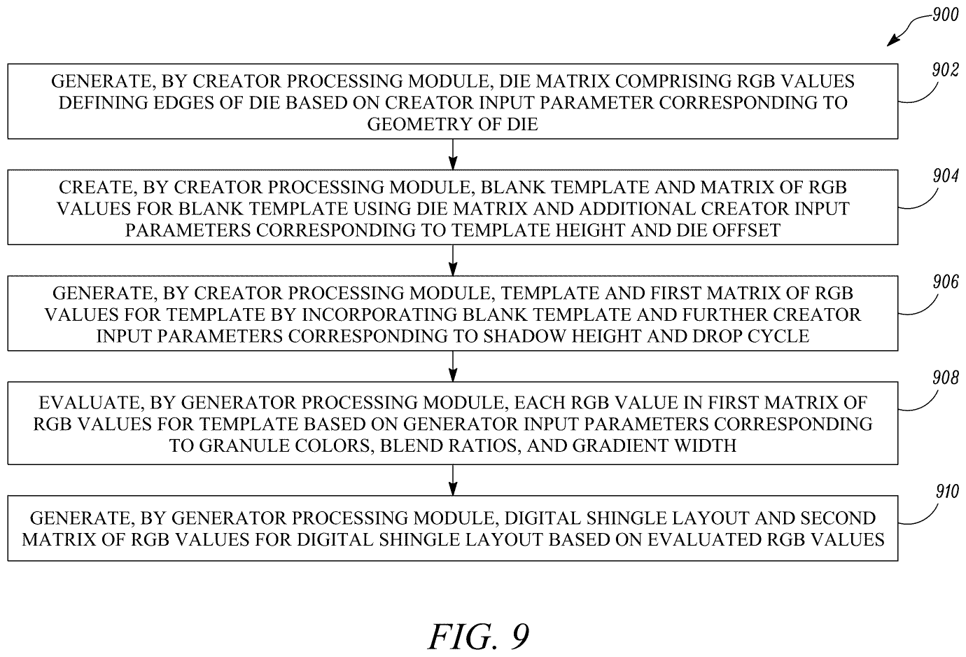

FIG. 9 is a flowchart of a method 900 for generating the digital shingle layout 100, in accordance with an embodiment of the present disclosure. It is to be noted that the method 900 is configured to be performed by the system 50 shown in FIG. 1. More specifically, the method 900 is configured to be performed collectively by the creator processing module 102 and the generator processing module 126 of the system 50.

Referring to FIGS. 1, 2, and 9, at step 902, the method 900 includes generating, by the creator processing module 102, the shingle outline matrix comprising digital color values defining edges 113 of the shingle outline 110 (shown in FIG. 3) based on the creator input parameter 104 corresponding to the geometry of the shingle outline 110. At step 904, the method 900 further includes creating, by the creator processing module 102, the blank digital shingle layout 120 (shown in FIG. 5) and the matrix 122 of digital color values for the blank digital shingle layout 120 using the shingle outline matrix and additional creator input parameters 104 corresponding to the digital shingle layout height H and shingle outline offset DO.

At step 906, the method 900 further includes generating, by the creator processing module 102, the digital shingle layout 106 (shown in FIG. 6) and the first matrix 108 of digital color values for the digital shingle layout 106 by incorporating the blank digital shingle layout 120 and further creator input parameters 104 corresponding to the shadow band height SH and the drop cycle. In some embodiments, generating the digital shingle layout 106 further includes replacing the digital color values in the matrix 122 of the blank digital shingle layout 120 with digital color values representing granule blends at corresponding locations for drop regions R and shadow bands 124 (shown in FIG. 6).

In some embodiments, the method 900 further includes converting, by the creator processing module 102, the first matrix 108 of digital color values for the digital shingle layout 106 to the image file format. The image file format of the digital shingle layout 106 is exportable. This image file of the digital shingle layout 106 is provided as an input to the generator processing module 126 which reconverts this image file to the first matrix 108 of digital color values corresponding to the digital shingle layout 106.

Referring to FIGS. 1, 7, and 9, at step 908, the method 900 further includes evaluating, by the generator processing module 126, each digital color value in the first matrix 108 of digital color values for the digital shingle layout 106 based on generator input parameters 128 corresponding to granule colors, blend ratios, and gradient width.

Upon evaluating the given digital color value in the first matrix 108 of digital color values for the digital shingle layout 106, the method 900 further includes verifying, by the generator processing module 126, if the given digital color value corresponds to the granule blend. Upon verifying that the given digital color value does not correspond to the granule blend, the method 900 further includes determining, by the generator processing module 126, that the given digital color value corresponds to the shingle outline edge 110 and retaining, by the generator processing module 126, that digital color value in the first matrix 108 of digital color values for the digital shingle layout 106.

Upon verifying that the given digital color value corresponds to the granule blend and receiving the generator input parameters 128 corresponding to the granule colors and blend ratios, the method 900 further includes randomly selecting, by the generator processing module 126, the preliminary granule digital color value based on corresponding granule colors and blend ratios. Upon selecting the preliminary granule digital color value, the method 900 further includes verifying, by the generator processing module 126, if the given digital color value corresponds to the drop region R.

Upon verifying that the given digital color value does not correspond to the drop region R, the method 900 further includes determining, by the generator processing module 126, that the given digital color value corresponds to the shadow band 124, and replacing, by the generator processing module 126, the given digital color value with the preliminary granule digital color value. The method 900 further includes adjusting, by the generator processing module 126, the preliminary granule digital color value to imitate realistic granule color variation to generate the new digital color value. The method 900 further includes replacing, by the generator processing module 126, the preliminary granule digital color value with the new digital color value.

Further, upon verifying that the given digital color value corresponds to the drop region R and receiving the generator input parameter 128 corresponding to the gradient width (shown in FIG. 8A), the method 900 further includes verifying, by the generator processing module 126, if the given digital color value is within the gradient region defined by the gradient width. Upon verifying that the given digital color value is outside the gradient region, the method 900 further includes replacing, by the generator processing module 126, the given digital color value with the preliminary granule digital color value. The method 900 further includes adjusting, by the generator processing module 126, the preliminary granule digital color value to imitate realistic granule color variation to generate the new digital color value. The method 900 further includes replacing, by the generator processing module 126, the preliminary granule digital color value with the new digital color value.

Upon verifying that the given digital color value is within the gradient region and receiving the generator input parameters 128 corresponding to the granule colors and blend ratios, the method 900 further includes checking, by the generator processing module 126, whether to change the preliminary granule digital color value to the gradient modified granule digital color value corresponding to the neighboring drop region. Upon checking that the preliminary granule digital color value is not to be changed to the gradient modified granule digital color value, the method 900 further includes replacing, by the generator processing module 126, the given digital color value with the preliminary granule digital color value. The method 900 further includes adjusting, by the generator processing module 126, the preliminary granule digital color value to imitate realistic granule color variation to generate the new digital color value. The method 900 further includes replacing, by the generator processing module 126, the preliminary granule digital color value with the new digital color value.

Upon checking that the preliminary granule digital color value is to be changed to the gradient modified granule digital color value, the method 900 further includes replacing, by the generator processing module 126, the given digital color value with the gradient modified granule digital color value. The method 900 further includes adjusting, by the generator processing module 126, the gradient modified granule digital color value to imitate realistic granule color variation to generate the new digital color value. The method 900 further includes replacing, by the generator processing module 126, the gradient modified granule digital color value with the new digital color value.

At step 910, the method 900 includes generating, by the generator processing module 126, the digital shingle layout 100 and the second matrix 130 of digital color values for the digital shingle layout 100 based on the evaluated digital color values. Specifically, upon evaluating each given digital color value in the first matrix 108 of digital color values for the digital shingle layout 108 based on the generator input parameters 128, the method 900 further includes generating, by the generator processing module 126, the digital shingle layout 100. The method 900 further includes creating, by the generator processing module 126, the second matrix 130 of digital color values for the digital shingle layout 100 by replacing each given digital color value in the digital shingle layout 108 with the corresponding evaluated digital color value. The method 900 further includes converting the second matrix 130 of digital color values for the digital shingle layout 100 to the image file format.

By generating the digital shingle layout 100, the system 50 and the method 900 of the present disclosure may eliminate a need for physical samples of different designs of shingles, thereby significantly reducing time and resources required for generating various samples of shingles. Users may digitally explore and experiment with various shingle designs, enabling the system 50 and the method 900 of the present disclosure to meet individual preferences and requirements. Further, the generation of the digital shingle layout 100 may ensure accurate distribution of granules comparable to physical samples, thereby enabling the user to more efficiently choose desirable granule colors and blend ratios for improving the appearance of shingles.

Incorporation of the two separate modules, (i.e., the creator processing module 102 and the generator processing module 126) in the system 50 may reduce time required in generation of the digital shingles, thereby increasing efficiency of overall process. The creator processing module 102 creates the digital shingle layout 106 and the first matrix 108 of digital color values for the digital shingle layout 106 and the generator processing module 126 generates the digital shingle layout 100 based on the digital shingle layout 100. Specifically, the creator processing module 102 creates the digital shingle layout 106 defining different regions in which different granule colors would be dropped by the generator processing module 126. Generally, the same digital shingle layout 106 may be used multiple times by changing the blend ratios and digital color values of granules in order to have different shingle layout 100. Therefore, repeatedly running the creator processing module 102 may be eliminated which may enhance efficiency, reduce processing load, and ensure consistent quality in the resulting digital shingles.

Referring again to FIGS. 1 and 9, the method 900 further includes transmitting the digital shingle layout 100 and the second matrix 130 of digital color values to a shingle manufacturing system 150. The shingle manufacturing system 150 includes a controller 152 configured to receive the digital shingle layout 100 and the second matrix 130 of digital color values, a material dispenser 154 configured to dispense granules based on the granule colors and blend ratios determined in the digital shingle layout 100, and a mechanical system 156 configured to transport a substrate 158 through the material dispenser 156. In some embodiments, the method 900 further includes applying the granules to the substrate 158 in accordance with the digital shingle layout 100 to form a shingle 111.

In some embodiments, the method 900 further includes curing the applied granules on the substrate 158 to finalize the shingle 111. In some embodiments, the curing includes heating the substrate 158 with the applied granules to a predetermined temperature for a predetermined duration. In some embodiments, the method 900 further includes inspecting the manufactured shingle 111 to ensure it conforms to the digital shingle layout 100. In some embodiments, the method 900 further includes comparing the colors or appearance of the manufactured shingle 111 with the colors in the digital shingle layout 100. In some embodiments, the method 900 further includes revising the generator processing module 128 based on the comparison of the colors. In some embodiments, revising the generator processing module 126 includes updating the generator input parameters 128 to improve an accuracy of the color matching. In some embodiments, the method 900 further includes using the revised generator processing module to adjust new shingle proposals. Moreover, adjusting new shingle proposals includes generating updated digital shingle layouts and corresponding matrices of digital color values based on the revised generator input parameters.

Such seamless transmission of the digital shingle layout 100 to the shingle manufacturing system 150 may enable precise and efficient production of shingles 111 based on the generated digital shingle layout 100. This integration of the system 50 with the shingle manufacturing system 150 may ensure that the generated shingle 111 perfectly aligns with the digital shingle layout 100, thereby reducing manual intervention and enhancing production accuracy. Additionally, the generated shingles 111 may be compared with the digital shingle layout 100 and adjustments may be made which further improves the flexibility and accuracy of the shingle manufacturing system 150.

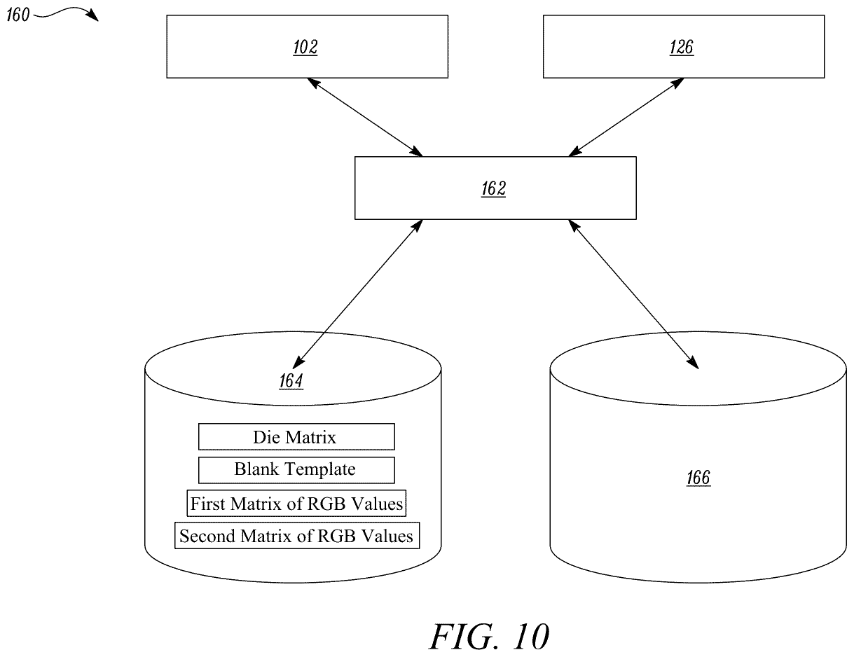

FIG. 10 is a schematic block diagram of a computer system 160 for generating the digital shingle layout 100, in accordance with an embodiment of the present disclosure. As shown, the computer system 160 includes at least one processor 162, a memory 164, and a non-transitory computer-readable storage medium 166. The memory 164 is configured to store the shingle outline matrix, the blank digital shingle layout 120, the first matrix 108 of digital color values, and the second matrix 130 of digital color values. The at least one processor 162 is configured to execute instructions (i.e., program code) stored in the non-transitory computer-readable storage medium 166 to perform the steps 902, 904, 906, 908, 910 of the method 900 described with reference to FIG. 9. The non-transitory computer-readable storage medium 166 contains instructions that, when executed by the at least one processor 162, cause the computer system 160 to perform the method steps 902, 904, 906, 908, 910 of the method 900.

Unless otherwise indicated, all numbers expressing feature sizes, amounts, and physical properties used in the specification and claims are to be understood as being modified by the term “about”. Accordingly, unless indicated to the contrary, the numerical parameters set forth in the foregoing specification and attached claims are approximations that can vary depending upon the desired properties sought to be obtained by those skilled in the art utilizing the teachings disclosed herein.

Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. A system for generating a digital shingle layout, the system comprising:
a creator processing module configured to receive and process creator input parameters to generate a digital shingle layout and create a first matrix of digital color values for the digital shingle layout, the creator input parameters comprising:
a geometry of a shingle outline, wherein the shingle outline corresponds to an exposed portion of a shingle in end-use application;
a digital shingle layout height which specifies the number of shingle outlines to be stacked in the digital shingle layout;
a shingle outline offset which specifies a lateral offset between every two adjacent shingle outlines for offsetting alignment of the shingle outline in the digital shingle layout; and
a drop cycle parameter selected from a group consisting of: identification numbers for specific granule blends to be dropped in different drop regions in the digital shingle layout, the width of each drop region, an order of dropping the granule blends in different drop regions, and location of drop regions relative to one another; and
a generator processing module configured to receive and process generator input parameters to generate the digital shingle layout and create a second matrix of digital color values for the digital shingle layout, the generator input parameters comprising:
the digital shingle layout;
granule colors which specify colors for the granule blends having different identification numbers; and
blend ratios which specify corresponding volume or mass percentage of granules in each granule blend.

2. The system of claim 1, wherein, upon receiving the creator input parameter corresponding to the geometry of the shingle outline, the creator processing module is configured to generate a shingle outline matrix comprising digital color values defining edges of the shingle outline; wherein, upon generating the shingle outline matrix and upon receiving the creator input parameters corresponding to the digital shingle layout height and the shingle outline offset, the creator processing module is configured to generate a blank digital shingle layout and create a matrix of digital color values for the blank digital shingle layout.

3. The system of claim 2, wherein the creator input parameters further comprise a shadow band height which specifies a height of a shadow band in each shingle outline in the digital shingle layout.

4. The system of claim 3, wherein, upon generating the blank digital shingle layout and upon receiving the creator input parameters corresponding to the shadow band height and the drop cycle, the creator processing module is configured to generate the digital shingle layout and create the first matrix of digital color values for the digital shingle layout.

5. The system of claim 4, wherein the creator processing module is further configured to generate the digital shingle layout by replacing the digital color values in the matrix of the blank digital shingle layout with digital color values representing granule blends at corresponding locations for drop regions and shadow bands.

6. The system of claim 1, wherein, upon receiving the generator input parameters corresponding to the digital shingle layout, the generator processing module is configured to:
evaluate each given digital color value in the first matrix of digital color values for the digital shingle layout; and
verify if each given digital color value corresponds to a granule blend.

7. The system of claim 6, wherein, upon verifying that a given digital color value does not correspond to the granule blend, the generator processing module is configured to:
determine that the given digital color value corresponds to shingle outline edge; and
retain that digital color value in the first matrix of digital color values for the digital shingle layout.

8. The system of claim 7, wherein, upon verifying that a given digital color value corresponds to the granule blend and upon receiving the generator input parameters corresponding to the granule colors and blend ratios, the generator processing module is configured to randomly select a preliminary granule digital color value based on corresponding granule colors and blend ratios.

9. The system of claim 1, wherein the shingle outline offset is redefined as a set, list, or array of values, wherein the number of values in the set, list, or array is equal to the digital shingle layout height, and the order of values corresponds to the order of digital shingle outlines that are stacked in the digital shingle blueprint.

10. A method for generating a digital shingle layout, the method comprising:
generating, by a creator processing module, a shingle outline matrix comprising digital color values defining edges of a shingle outline based on a creator input parameter corresponding to a geometry of the shingle outline;
creating, by the creator processing module, a blank digital shingle layout and a matrix of digital color values for the blank digital shingle layout using the shingle outline matrix and additional creator input parameters corresponding to a digital shingle layout height and a shingle outline offset;
generating, by the creator processing module, a digital shingle layout and a first matrix of digital color values for the digital shingle layout by incorporating the blank digital shingle layout and further creator input parameters corresponding to a shadow band height and a drop cycle;
evaluating, by a generator processing module, each digital color value in the first matrix of digital color values for the digital shingle layout based on generator input parameters corresponding to granule colors, blend ratios, and a gradient width;
generating, by the generator processing module, the digital shingle layout and a second matrix of digital color values for the digital shingle layout based on the evaluated digital color values.

11. The method of claim 10, wherein, among the creator input parameters:
the shingle outline corresponds to an exposed portion of a shingle in end-use application;
the digital shingle layout height specifies the number of shingle outlines to be stacked in the digital shingle layout;
the shingle outline offset specifies a lateral offset between every two adjacent shingle outlines for offsetting alignment of the shingle outlines in the digital shingle layout;
the shadow band height specifies a height of a shadow band in each shingle outline in the digital shingle layout; and
the drop cycle specifies identification numbers for specific granule blends to be dropped in different drop regions in the digital shingle layout, the width of each drop region, an order of dropping the granule blends in different drop regions, and location of drop regions relative to one another.

12. The method of claim 10, wherein generating the digital shingle layout further comprises:
replacing the digital color values in the matrix of the blank digital shingle layout with digital color values representing granule blends at corresponding locations for drop regions and shadow bands.

13. The method of claim 10, wherein, upon evaluating a given digital color value in the first matrix of digital color values for the digital shingle layout, the method further comprises:
verifying, by the generator processing module, if the given digital color value corresponds to a granule blend; wherein, upon verifying that a given digital color value does not correspond to the granule blend, the method further comprises:
determining, by the generator processing module, that the given digital color value corresponds to the shingle outline edge; and
retaining, by the generator processing module, that digital color value in the first matrix of digital color values for the digital shingle layout.

14. The method of claim 13, wherein, upon verifying that a given digital color value corresponds to the granule blend and receiving the generator input parameters corresponding to the granule colors and blend ratios, the method further comprises:
randomly selecting, by the generator processing module, a preliminary granule digital color value based on corresponding granule colors and blend ratios.

15. The method of claim 14, wherein, upon selecting the preliminary granule digital color value, the method further comprises:
verifying, by the generator processing module, if the given digital color value corresponds to a drop region.

16. The method of claim 10, wherein the creator processing module and the generator processing module are implemented on a computer system comprising at least one processor, a memory, and a non-transitory computer-readable storage medium, wherein:
the at least one processor is configured to execute instructions stored in the non-transitory computer-readable storage medium to perform the steps of receiving, generating, generating, evaluating, determining, and generating as recited in claim 29;
the memory is configured to store the shingle outline matrix, blank digital shingle layout, first matrix of digital color values, and second matrix of digital color values; and
the non-transitory computer-readable storage medium contains instructions that, when executed by the at least one processor, cause the computer system to perform the method steps as recited in claim 10.

17. The method of claim 10, further comprising:
transmitting the digital shingle layout and the second matrix of digital color values to a shingle manufacturing system, wherein the shingle manufacturing system comprises:
a controller configured to receive the digital shingle layout and the second matrix of digital color values;
a material dispenser configured to dispense granules based on the granule colors and blend ratios determined in the digital shingle layout; and
a mechanical system configured to transport a substrate through the material dispenser.

18. The method of claim 17, further comprising:
applying the granules to the substrate in accordance with the digital shingle layout to form a shingle;
curing the applied granules on the substrate to finalize the shingle, wherein the curing comprises:
heating the substrate with the applied granules to a predetermined temperature for a predetermined duration.

19. The method of claim 18, further comprising:
comparing the appearance of the manufactured shingle with the appearance in the digital shingle layout;
revising the generator processing module based on the comparison of the colors; and
using the revised generator processing module to adjust new shingle proposals.

20. The method of claim 19, wherein adjusting new shingle proposals comprises:
generating updated digital shingle layouts and corresponding matrices of digital color values based on the revised generator input parameters.
